(19) United States
(12) Patent Application Publication
(10) Pub. No.: US 2025/0364369 A1
(43) Pub. Date: Nov. 27, 2025

(54) DIELECTRIC SOCKET TO FACILITATE THROUGH-SEMICONDUCTOR VIA STRUCTURE

(71) Applicant: Intel Corporation, Santa Clara, CA (US)

(72) Inventor: Denzil S. Frost, Rio Rancho, NM (US)

(73) Assignee: Intel Corporation, Santa Clara, CA (US)

(21) Appl. No.: 18/671,404

(22) Filed: May 22, 2024

(51) Int. Cl. H01L 23/48; H01L 21/768; H01L 23/522

(52) U.S. Cl. CPC H01L 23/481; H01L 21/76898; H01L 23/5226

(57) ABSTRACT

Techniques are provided herein for forming a through-semiconductor via (TSV) that extends through an entire thickness of a frontside interconnect region to provide a connection to a backside interconnect layer. The TSV is arranged within a dielectric socket that extends through an entire thickness of multiple layers included in the frontside interconnect region. The TSV extends through the device layer of a die and through each of multiple or all frontside interconnect layers of a frontside interconnect region. According to some embodiments, a dielectric socket is first formed through the frontside interconnect region and through the device layer to provide an isolated region for the TSV. A deep recess may then be etched through the entire height of the dielectric socket from the backside of the structure and filled with a conductive material to form the TSV. A backside conductive layer may be subsequently formed to contact the TSV.

### BACKGROUND

As integrated circuits continue to scale downward in size, a number of challenges arise. As density of devices increases, the available space on a given die dwindles rapidly. Some structures beyond the semiconductor devices, such as various interconnect structures, can require multiple patterning steps and increase the complexity of the fabrication. Accordingly, there remain a number of non-trivial challenges with respect to fabricating certain structures in an integrated circuit.

### BRIEF DESCRIPTION OF THE DRAWINGS

FIG. 1 is a cross-sectional view that illustrates an example portion of an integrated circuit configured with a via connected to a backside conductive layer and extending through an entire thickness of a frontside interconnect region, in accordance with some embodiments of the present disclosure.

FIGS. 2A-2G′ illustrate cross-sectional views of a process for forming a via connected to a backside conductive layer and extending through an entire thickness of a frontside interconnect region within a dielectric socket, in accordance with some embodiments of the present disclosure.

FIG. 3 illustrates a cross-section view of a chip package containing one or more semiconductor dies, in accordance with some embodiments of the present disclosure.

FIG. 4 is a flowchart of a method for forming a via connected to a backside conductive layer and extending through an entire thickness of a frontside interconnect region within a dielectric socket, in accordance with some embodiments of the present disclosure.

FIG. 5 illustrates a computing system including one or more integrated circuits, as variously described herein, in accordance with some embodiments of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein for forming a through-semiconductor via (TSV) that extends through an entire thickness of a frontside interconnect region to provide a connection to a backside interconnect layer. The TSV is arranged within a dielectric socket that extends through an entire thickness of the frontside interconnect region. The TSV may be, for example, a microscale structure (e.g., width between 3 and 10 micrometers) that extends through the device layer of a die and through each frontside interconnect layer of a frontside interconnect region, although other examples may be scaled down or up, or otherwise appropriately sized for a given application and process node, including those examples having sub-micron dimensions. The device layer may include any number of semiconductor devices. According to some embodiments, a dielectric socket is first formed through the frontside interconnect region and through the device layer to provide an isolated region for the TSV. A deep recess may then be etched through the entire height of the dielectric socket from the backside of the structure, such that the recess also extends at least partially into a carrier substrate bonded above the frontside interconnect region. The deep recess may be filled with a conductive material to form the TSV, and a backside conductive layer may be subsequently formed to contact a bottom surface of the TSV. One or more connections to the top surface of the TSV may be made through the carrier substrate or by recessing the top surface of the carrier substrate to expose the top surface of the TSV. The term TSV is often used to refer to through-silicon vias, but in the present disclosure is used more broadly to include a via that passes through any semiconductor material, not just silicon. Numerous configurations and variations will be apparent in light of this disclosure.

### General Overview

As previously noted above, it can be challenging to form certain integrated circuit structures as space becomes more limited. Numerous structures beyond the active devices (e.g., transistors) must be arranged on the die as well, including interconnect structures. Some via structures are arranged to provide power or signal to conductive layers within frontside or backside interconnect regions. When delivering power or signal to a backside interconnect layer, the via is isolated from the frontside interconnect layers. This requires many masking steps to provide metal-free zones, guard rings, and dummy fill areas throughout each of the frontside interconnect layers, thus increasing the complexity of frontside or back end of line (BEOL) processing.

Techniques are provided herein for forming a TSV structure through a preformed dielectric socket that reduces frontside/BEOL masking complexity by removing the need for forming various isolation structures (e.g., metal-free zones, guard rings, and dummy fill areas) in each of the frontside interconnect layers, according to some embodiments. Following the formation of each of the frontside interconnect layers, an etching process is performed to form a relatively large recess through all of the frontside interconnect layers and also through the device layer beneath the frontside interconnect layers. The recess may be filled with one or more dielectric materials to form a dielectric socket. The dielectric socket provides an isolated region through which to form the TSV. In some such examples, the socket may have a tapered profile, as seen in cross-section, such that the width of the socket proximate to the device layer is smaller than the width of the opposite end of the socket. A carrier substrate may be bonded above the frontside interconnect layers (thus allowing the integrated circuit structure or wafer to be flipped to facilitate backside processing) and the substrate below the device layer is removed. The removal of the substrate may expose a bottom surface of the dielectric socket. A backside recess is then formed through the dielectric socket and extending into at least a portion of the carrier substrate. The backside recess may be filled with one or more conductive materials to form the TSV. According to some embodiments, the dielectric socket provides isolation between the TSV and the device layer and between the TSV and each of the frontside interconnect layers. Further backside processing may be performed to form one or more backside interconnect layers, with at least one backside conductive layer contacting the TSV. In some such examples, the TSV can be provided by patterning first and second masks, the first mask patterned during frontside processing to provide the socket, and the second mask patterned during backside processing to provide the conductive via within the socket. Thus, masking complexity can be significantly reduced, relative to standard processing.

According to an embodiment, an integrated circuit includes a plurality of semiconductor devices within a device layer, a first interconnect region above the device layer and having a plurality of first interconnect layers, a second interconnect region below the device layer and having one or more second interconnect layers, a dielectric structure extending through an entire thickness of the first interconnect region and an entire thickness of the device layer, and a conductive via extending through an entire thickness of the dielectric structure and contacting at least one conductive layer within any of the one or more second interconnect layers.

According to another embodiment, an electronic device includes a chip package having one or more dies. At least one of the one or more dies includes a device layer comprising any number of semiconductor devices, a first interconnect region above the device layer and having a plurality of first interconnect layers, a second interconnect region below the device layer and having one or more second interconnect layers, a dielectric structure extending through an entire thickness of the first interconnect region and an entire thickness of the device layer, and a conductive via extending through an entire thickness of the dielectric structure and contacting at least one conductive layer within any of the one or more second interconnect layers.

According to another embodiment, an integrated circuit includes a device layer comprising any number of semiconductor devices, a first interconnect region above the device layer and having a plurality of first interconnect layers, a second interconnect region below the device layer and having one or more second interconnect layers, a dielectric structure extending through an entire thickness of the first interconnect region and an entire thickness of the device layer, and a conductive via extending through an entire thickness of the dielectric structure and contacting at least one conductive layer within any of the one or more second interconnect layers. The dielectric structure has a tapered profile such that a top surface of the dielectric structure adjacent to a top surface of the first interconnect region is wider than a bottom surface of the dielectric structure adjacent to a top surface of the second interconnect region. In some such examples, the conductive via has a tapered profile such that a bottom surface of the conductive via is wider than a top surface of the conductive via. In some such examples, the dielectric structure forms a wall between semiconductor devices of the device layer and the conductive via, and the wall thickness of the dielectric structure decreases as the taper of the dielectric structure progresses downward toward the device layer.

According to another embodiment, a method of forming an integrated circuit includes: forming any number of semiconductor devices in a device layer over a first substrate; forming an interconnect region over the device layer; forming a first recess through an entire thickness of the interconnect region and through an entire thickness of the device layer; forming one or more dielectric materials within the first recess to create a dielectric structure; bonding a second substrate to a top surface of the interconnect region; removing at least a portion of the first substrate; forming a second recess through an entire thickness of the dielectric structure from beneath the device layer; and forming one or more conductive materials within the second recess to create a conductive via.

The techniques can be used with any type of planar and non-planar transistors within the device layer, including finFETs (sometimes called double-gate transistors, or tri-gate transistors), nanowire and nanoribbon transistors (sometimes called gate-all-around transistors), and thin film transistors, to name a few examples. The source and drain regions can be, for example, epitaxial regions that are deposited during an etch-and-replace source/drain forming process, or doped regions of the substrate in which the transistors are formed. The dopant-type in the source and drain regions will depend on the polarity of the corresponding transistor. The gate structure can be implemented with a gate-first process or a gate-last process (sometimes called a remove metal gate, or RMG, process). Any number of semiconductor materials can be used in forming the transistors to which power is being supplied by a buried or backside power rail, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the presence of one or more TSVs extending through a dielectric socket that itself extends through an entire thickness of the frontside interconnect region and the device layer. In some examples, such tools may indicate that the dielectric socket tapers inwards with a greater width adjacent to the top of the frontside interconnect region compared to its width adjacent to the bottom of the frontside interconnect region (near the device layer). In some examples, a conductive via within the socket may have a reverse taper that tapers inwards with a greater width adjacent to the device layer compared to its width adjacent to the top of the frontside interconnect region. The wall thickness of the socket (as seen in a cross-sectional profiled) may decrease as the socket taper progresses downward toward the device layer.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the materials has an element that is not in the other material.

### Architecture

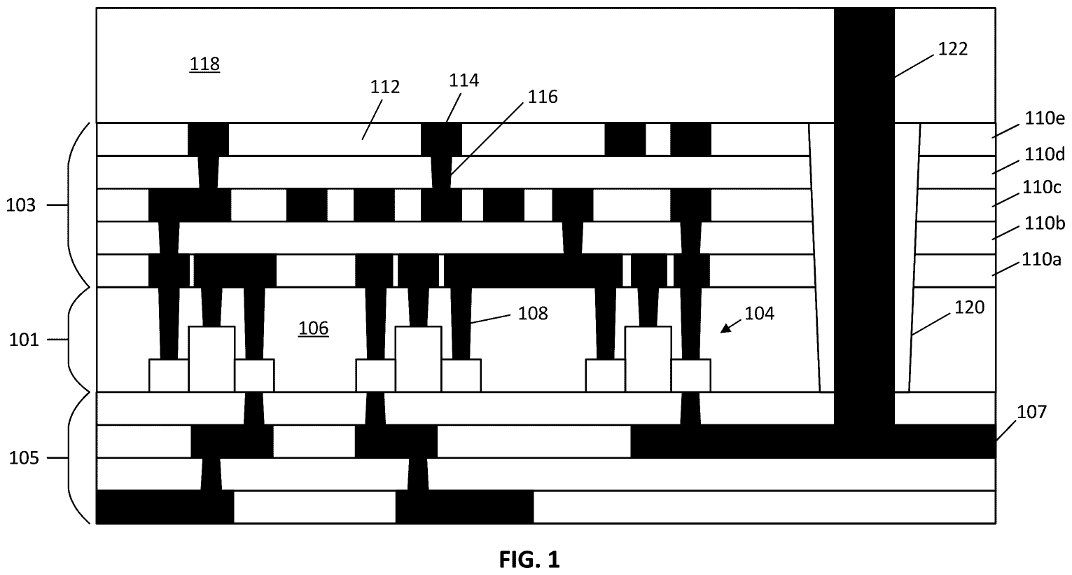

FIG. 1 is a cross-sectional view that illustrates an example portion of an integrated circuit having interconnect regions both above and below a plurality of semiconductor devices within a device layer, in accordance with an embodiment of the present disclosure. The semiconductor devices in this example are non-planar metal oxide semiconductor (MOS) transistors, such as tri-gate or gate-all-around (GAA) transistors, although other transistor topologies and types can also benefit from the techniques provided herein, as will be appreciated (e.g., planar transistors, forksheet transistors, thin film transistors, or any other transistors to which contact can be made). It should be noted that the relative sizes of different elements have been exaggerated and are not drawn to scale for illustrative purposes.

According to some embodiments, the integrated circuit includes a device region 101 (sometimes referred to as a device layer), a frontside interconnect region 103 over device region 101, and a backside interconnect region 105 beneath device region 101. Device region 101 may include a plurality of semiconductor devices 104 along with one or more other layers or structures associated with the semiconductor devices 104. For example, device region 101 can also include one or more dielectric layers 106 that surround active portions or contacts of the semiconductor devices 104. Device region 101 may also include one or more conductive contacts 108 that provide electrical contact to transistor elements such as gate structures, drain regions, or source regions. Conductive contacts 108 include, for example, tungsten, although other metal or metal alloy materials may be used as well. Conductive contacts 108 may also be a part of, or otherwise include, what is sometimes called a local interconnect, which is considered part of the device region and usually formed prior to any backend processing. In some examples, device region 101 includes a semiconductor device layer from which the semiconductor channels of the transistors are formed.

Frontside interconnect region 103 includes a plurality of interconnect layers 110a-110c stacked over one another. Each interconnect layer can include a dielectric material 112 along with one or more different conductive features. Dielectric material 112 can be any dielectric, such as silicon oxide, silicon oxycarbide, silicon nitride, or silicon oxynitride. Dielectric material 112 may be deposited using any known dielectric deposition technique such as chemical vapor deposition (CVD), plasma-enhanced chemical vapor deposition (PECVD), flowable CVD, spin-on dielectric, or atomic layer deposition (ALD). The one or more conductive features can include conductive traces 114 and conductive vias 116 arranged in any pattern across the interconnect layers 110a-110e to carry signal and/or power voltages to/from the various semiconductor devices 104. A conducive via, such as conductive via 116, may extend through an interconnect layer to connect between conductive traces on an upper interconnect layer and a lower interconnect layer. In other cases, a via 116 may only extend part way through a given interconnect layer. Although frontside interconnect region 103 is illustrated with only five interconnect layers, any number of interconnect layers can be used within frontside interconnect region 103. Also, this example shows vias and lines in different interconnect layers, in both single and dual damascene configurations. In other examples, vias and lines may also exist within the same interconnect layer, such as in the case of some dual damascene configurations.

In some embodiments, device region 101 is arranged on or over backside interconnect region 105. Backside processing may be used to remove the substrate from beneath device region 101 and to form any number of backside interconnect layers that are generally similar to interconnect layers 110a-110e. Although backside interconnect region 105 is illustrated with only four interconnect layers, any number of interconnect layers can be used within backside interconnect region 105. According to some embodiments, a backside conductive layer 107 may be provided to carry power rail signals or a ground signal (e.g., VDD, VSS, or GND). Any number of backside interconnect layers including dielectric material with patterned conductive trances and vias may be formed.

Any of conductive traces 114 and conductive vias 116 can include any number of conductive materials, with some examples including copper, ruthenium, tungsten, cobalt, molybdenum, and alloys thereof. In some cases, any of conductive traces 114 and conductive vias 116 include a relatively thin liner or barrier, such as titanium nitride, titanium silicide, tungsten carbo-nitride (WCN), PVD or ALD tungsten, or tantalum nitride.

It should be noted that each of the various conductive vias 116 and conductive contacts 108 are shown with tapered profiles to indicate a more natural appearance due to the etching process used to form the openings. Any degree of tapering may be observed depending on the etch parameters used and the thickness of the dielectric layer being etched through. Furthermore, conductive vias may be stacked one over the other through different dielectric layers of frontside interconnect region 103. However, in some examples, a single via recess may be formed through more than one dielectric layer yielding a taller, more tapered conductive via that extends through two or more dielectric layers.

The various interconnect layers of frontside interconnect region 103 may not all be the same thickness. According to some embodiments, the interconnect layers increase in thickness moving upwards towards the top of frontside interconnect region 103. Thus, the top-most interconnect layer may have the greatest thickness while the bottom-most interconnect layer of frontside interconnect region 103 may have the smallest thickness. In some examples, the top-most interconnect layer may have a thickness in the range of several micrometers (e.g., 1-4 μm), while the bottom-most interconnect layer may have a thickness of less than 50 nm.

According to some embodiments, a carrier substrate 118 is bonded to a top of frontside interconnect region 103. Carrier substrate 118 may be a semiconductor substrate (e.g., silicon substrate) or any other suitable material with sufficient strength and compatibility with integrated circuit fabrication processes. In some embodiments, carrier substrate 118 is at least several micrometers thick, such as at least 50 micrometers thick, or between 100 micrometers and 300 micrometers thick. Carrier substrate 118 may be bonded to the top of frontside interconnect region 103 using any suitable bonding technique, such as direct wafer bonding, plasma bonding, eutectic bonding, or anodic bonding. In some examples, carrier substrate 118 is sacrificial, in that it's used only to facilitate backside processing. In such cases, another carrier substrate may be bonded to the bottom of backside interconnect region 105 and carrier substrate 118 may be removed and replaced with another substrate and/or one or more additional interconnect layers subsequently formed on frontside interconnect region 103.

According to some embodiments, a dielectric socket 120 extends through an entire thickness of device region 101 in an area separate from semiconductor devices 104. Dielectric socket 120 further extends through an entire thickness of frontside interconnect region 103, in this particular example. In some examples, dielectric socket 120 includes a fill of silicon dioxide, although other dielectric materials may be used as well, such as silicon nitride, silicon carbide, or silicon oxynitride. Dielectric socket 120 may have a greatest width (e.g., along its top surface), for example, of between about 3 micrometers and 15 micrometers, such as between 5 micrometers and 10 micrometers. Other examples may be scaled upward (e.g., >15 micrometers) or downward (e.g., sub-micron such as 500 nm or smaller), depending on factors such as the number of interconnect layers within frontside interconnect region 103, the process node, and application of the integrated circuit. According to some embodiments, dielectric socket 120 exhibits a tapered profile with a smaller width at its bottom surface (e.g., coplanar with the bottom surface of device region 101) compared to its top surface (e.g., coplanar with a top surface of frontside interconnect region 103). In other examples, dielectric socket 120 may have a relatively straight profile, such as may occur when the height-to-width ratio of the socket is relatively low (e.g., 4:1 or less, such as 2:1).

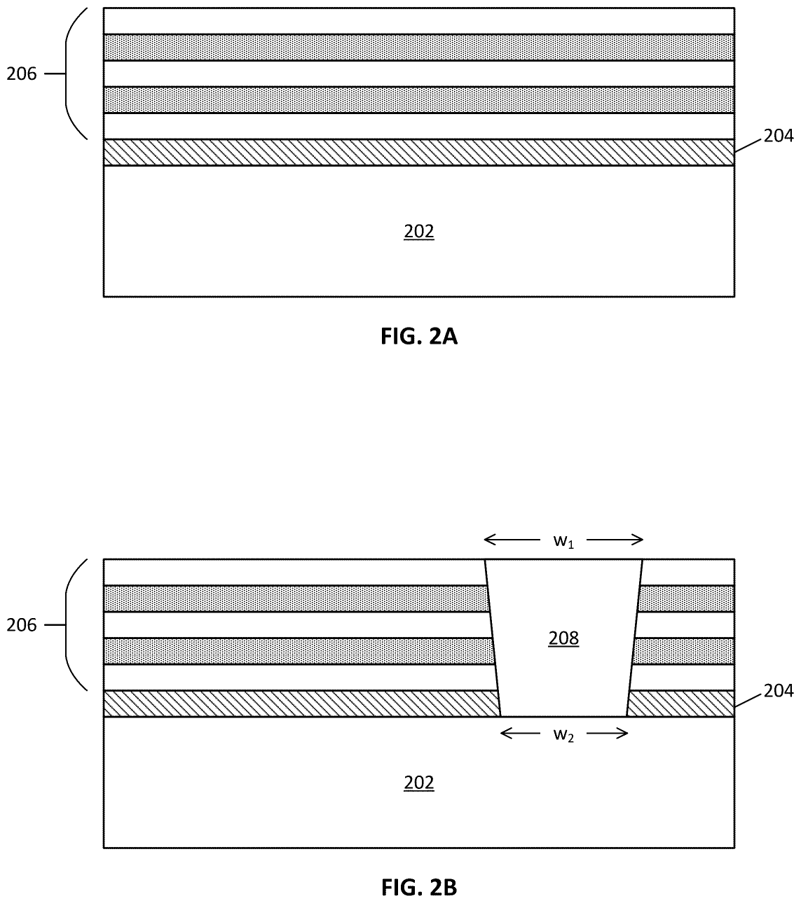

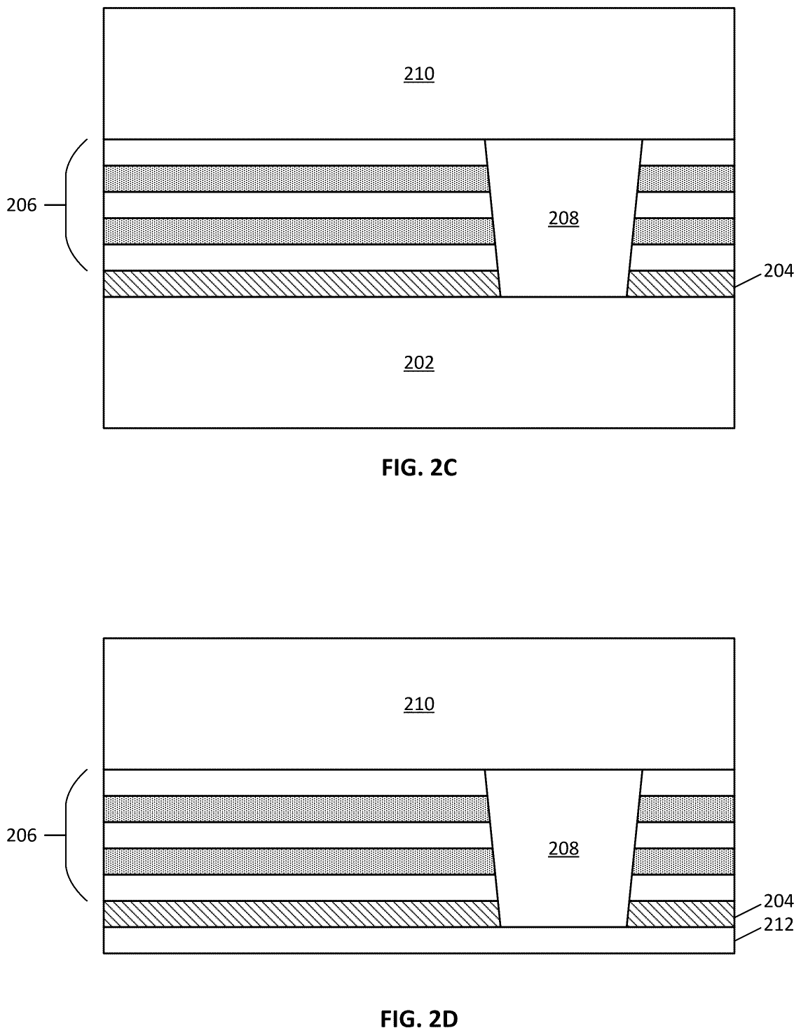

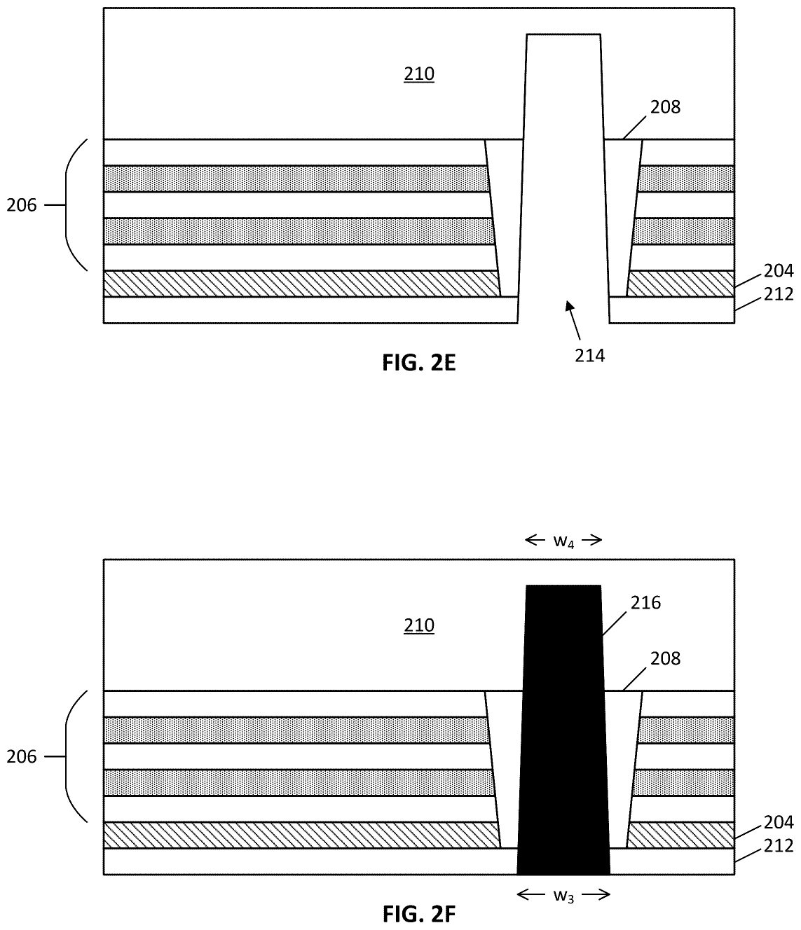

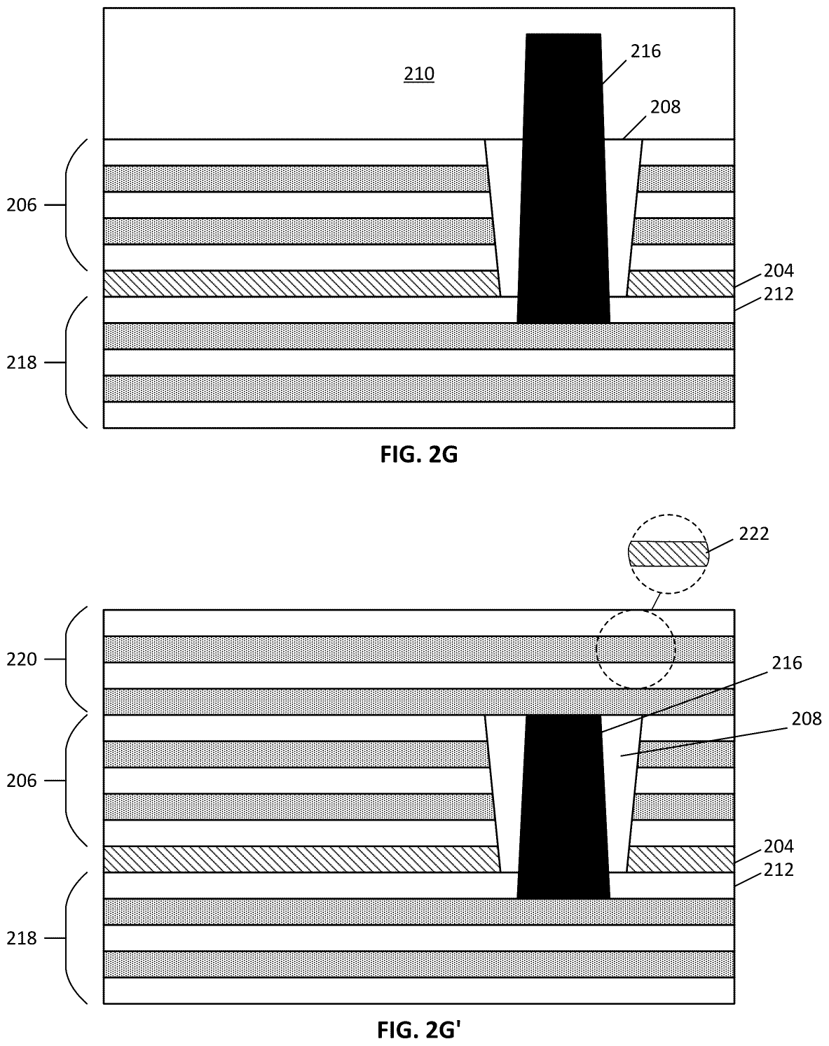

According to some embodiments, a conductive structure 122, also referred to as TSV structure 122 extends through the entire height of dielectric socket 120. TSV structure 122 may further extend into at least a portion of carrier substrate 118, or through an entire thickness of carrier substrate 118, or a structure of one or more layers that subsequently replaces carrier substrate 118. TSV structure 122 may include any number of conductive materials, such as single conductive fill, or a liner or barrier layer (e.g., tantalum, titanium, or a nitride thereof) with a conductive fill on the conductive liner. TSV structure 122 may include any of copper, ruthenium, tungsten, cobalt, molybdenum, titanium, tantalum, or alloys thereof, to name a few examples. According to some embodiments, TSV structure 122 contacts at least one backside conductive layer 107 and provides a conductive pathway to a top surface of the die (e.g., at or near a top surface of carrier substrate 118 or its replacement). As shown in this example, TSV structure 122 may be relatively straight (untapered), and the lateral thickness of the socket 120 to either side of TSV structure 122 decreases as the socket taper progresses toward the device region 101. In other examples, TSV structure 122 may have a taper that is reversed with respect to the socket taper (such as shown in the example of FIG. 2G).

### Fabrication Methodology

FIGS. 2A-2G are cross-sectional views that collectively illustrate an example process for forming a portion of an integrated circuit, in accordance with an embodiment of the present disclosure. Each figure shows an example structure that results from the process flow up to that point in time, so the depicted structure evolves as the process flow continues, culminating in the structure shown in FIG. 2G, which is similar to the structure illustrated in FIG. 1. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but the present disclosure is not intended to be limited to any specific such materials or parameters, as will be appreciated.

FIG. 2A is a cross-sectional view taken through a portion of a substrate 202. Substrate 202 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, the substrate can be a semiconductor-on-insulator substrate having a desired semiconductor layer over a buried insulator layer (e.g., silicon over silicon dioxide). Alternatively, the substrate can be a multilayer substrate or superlattice suitable for forming nanowires or nanoribbons (e.g., alternating layers of silicon and SiGe, or alternating layers indium gallium arsenide and indium phosphide). Any number of substrates can be used.

According to some embodiments, a device layer 204 is provided over substrate 202. In one example, device layer 204 includes a single layer of silicon, germanium, or silicon germanium suitable for forming finFET devices. In some examples, device layer 204 includes alternating layers of silicon and silicon germanium suitable for making gate-all-around (GAA) transistors. In any case, device layer 204 has a total thickness of less than 500 nm, such as between 30 nm and 150 nm. In some embodiments, device layer 204 includes the same semiconductor material as substrate 202.

According to some embodiments, following the formation of any number of semiconductor devices within device layer 204, a frontside interconnect region 206 is formed over device layer 204. Frontside interconnect region 206 may be similar to frontside interconnect region 103 described above with reference to FIG. 1. Accordingly, frontside interconnect region 206 may include any number of interconnect layers. Each interconnect layer includes any number of patterned conductive vias and/or conductive traces within a dielectric material (e.g., silicon dioxide).

FIG. 2B is a cross-sectional view of the structure depicted in FIG. 2A, after the formation of a dielectric socket 208 through both device layer 204 and frontside interconnect region 206. A recess may be formed through an entire thickness of both device layer 204 and frontside interconnect region 206 using a suitable anisotropic etching technique such as reactive ion etching (RIE). The recess may extend partially into substrate 202.

According to some embodiments, a dielectric fill may be used to substantially fill the recess and form dielectric socket 208. The dielectric fill may be any suitable dielectric material such as silicon dioxide, silicon nitride, silicon oxynitride, or silicon oxycarbonitride. In some examples, more than one dielectric material is deposited within the recess to form dielectric socket 208. A top surface of dielectric socket 208 may be polished using, for example, chemical mechanical polishing (CMP), such that the top surface of dielectric socket 208 is substantially coplanar (e.g., within 2 nm) with a top surface of frontside interconnect region 206.

Dielectric socket 208 may have a first width w₁ along its top surface between about 3 micrometers and 15 micrometers, such as between about 5 micrometers and about 10 micrometers. According to some embodiments, the width of dielectric socket 208 tapers down such that the bottom of dielectric socket 208 has a second width w₂ that is less than the first width w₁. In some examples, second width w₂ is at least 50 nm, at least 100 nm, or at least 150 nm less than the first width w₁.

FIG. 2C is a cross-sectional view of the structure depicted in FIG. 2B, after the bonding of a carrier substrate 210 to a top surface of frontside interconnect region 206, according to some embodiments. Carrier substrate 210 may also be bonded to or directly over a top surface of dielectric socket 208. Carrier substrate 210 may include any suitable circuit substrate material, such as a semiconductor material or a glass substrate. Carrier substrate 210 may be bonded to frontside interconnect region 206 using any suitable bonding technique, such as direct wafer bonding, plasma bonding, eutectic bonding, or anodic bonding. In some examples, carrier substrate 210 becomes an integral part of the integrated circuit being formed (such as shown in the example of FIG. 2G); in other examples, carrier substrate 210 may be sacrificial, in that it is subsequently removed (e.g., via CMP) and replaced with one or more layers, such as one or more additional interconnect and/or device layers provided on frontside interconnect region 206 (such as shown in the example of FIG. 2G′).

FIG. 2D is a cross-sectional view of the structure depicted in FIG. 2C, after the removal of substrate 202 from the backside and the formation of a backside dielectric layer 212, according to some embodiments. Substrate 202 may be removed using any number of or combination of techniques such as dry etching, wet etching, polishing, or grinding. In some examples, the backside of substrate 202 is polished or grinded down until the lower surface of dielectric socket 208 is exposed. In some examples, the backside of substrate 202 is polished or grinded down until the lower surface of one or more materials within device layer 204 are exposed.

Dielectric layer 212 may include any suitable dielectric material, such as silicon dioxide, silicon nitride, or silicon oxynitride, to name a few examples. In some examples, dielectric layer 212 is a first backside interconnect layer of a backside interconnect region. Accordingly, some portions of dielectric layer 212 may be patterned with one or more conductive structures to facilitate backside power or signal routing.

FIG. 2E is a cross-sectional view of the structure depicted in FIG. 2D following the formation of a deep backside recess 214 through an entire height of dielectric socket 208, according to some embodiments. Another RIE process may be used to etch through each of backside dielectric layer 212 and dielectric socket 208. According to some embodiments, backside recess 214 further extends into at least a portion of carrier substrate 210. In some examples, the presence of dielectric socket 208 can act as an alignment mark to aid in patterning the hard mask or photoresist used to protect all backside portions not etched by the RIE process. Backside recess 214 is aligned within dielectric socket 208 such that no portions of device layer 204 or frontside interconnect region 206 are exposed within backside recess 214. According to some embodiments, backside recess 214 tapers inwards such that the width of the recess decreases along its depth (measured from the backside with dielectric layer 212 towards the frontside with carrier substrate 210).

FIG. 2F is a cross-sectional view of the structure depicted in FIG. 2E following the formation of one or more conductive materials within backside recess 214 to form TSV 216, according to some embodiments. Any suitable conductive material can be used, such as any of copper, ruthenium, tungsten, cobalt, molybdenum, or alloys thereof, to name a few examples. In some examples, TSV 216 includes a conductive liner and a conductive fill on the conductive liner. The conductive liner may be a barrier layer material (such as tantalum nitride or titanium nitride), and the conductive fill includes any of copper, ruthenium, tungsten, cobalt, or molybdenum.

According to some embodiments, TSV 216 tapers inwards as dictated by the tapered profile of backside recess 214. For example, TSV 216 may have a first width w₃ at its bottom surface and a second width w₄ at its top surface. The first width w₃ may be between about 2 micrometers and about 8 micrometers, such as between about 4 micrometers and about 5 micrometers. The second width w₄ may be at least 50 nm, at least 100 nm, or at least 150 nm less than the first width w₃.

FIG. 2G is a cross-sectional view of the structure depicted in FIG. 2F, following the formation of additional backside interconnect layers to create a backside interconnect region 218, according to some embodiments. Backside interconnect region 218 may include any number of interconnect layers to route signal or power to any of the semiconductor devices within device layer 204. According to some embodiments, at least one backside conductive layer within a given backside interconnect layer contacts TSV 216. In some embodiments, the top of TSV 216 may connect to an off-chip power or ground source. In one example, the top surface of carrier substrate 210 is recessed to expose the top surface of TSV 216 to facilitate the connection off-chip. In another example, an additional contact is formed through carrier substrate 210 to contact the top surface of TSV 216 and the additional contact facilitates the connection off-chip. In any case, a rail power or ground signal may be provided through TSV 216 to the backside conductive layer. The backside conductive layer may be configured to route the power or ground signal to any number of semiconductor devices.

In still other embodiments, carrier substrate 210 can be removed and replaced with one or more additional layers. To maintain structural integrity, another carrier substrate may first be bonded to the bottom of backside interconnect region 218. Carrier substrate 210 can be removed, for example, by a CMP process that planarizes the structure down to the upper most surface of frontside interconnect region 206, including any extension of conductive via 216 into that region. FIG. 2G′ shows one such example, where carrier substrate 210 has been removed and replaced with region 220 having a number of additional interconnect layers, which can be used for further routing of signals and/or power, including to or from TSV 216. As shown in the dashed pull-out circle, the one or more additional layers of region 220 may include an additional device layer 222. In one such example, region 220 with the additional interconnect layers (and device layer 222, in some such examples) may be formed directly on the planarized surface that includes an exposed upper surface of TSV 216, so as to effectively be considered part of frontside interconnect region 206, but may also be considered a second or separate interconnect region above region 206. In still other examples, region 220 with the additional interconnect layers and device layer 222 may be formed on a separate substrate or wafer, which is then bonded to the planarized substrate or wafer that includes TSV 216. In this way, the devices and materials of device layer 204 are not subjected to processing environments used in forming device layer 222.

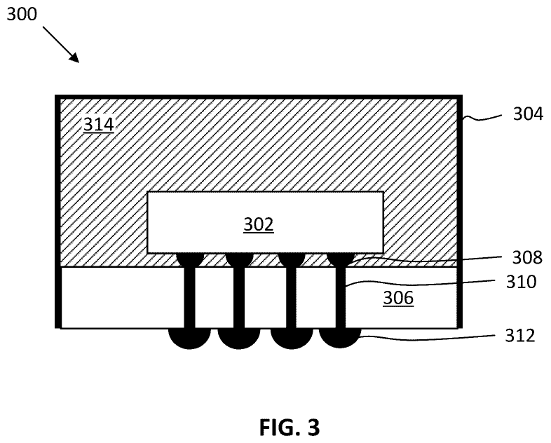

FIG. 3 illustrates an example embodiment of a chip package 300, in accordance with an embodiment of the present disclosure. As can be seen, chip package 300 includes one or more dies 302. One or more dies 302 may include at least one integrated circuit having a structure as described in any of the aforementioned embodiments. One or more dies 302 may include any other circuitry used to interface with other devices formed on the dies, or other devices connected to chip package 300, in some example configurations.

As can be further seen, chip package 300 includes a housing 304 that is bonded to a package substrate 306. The housing 304 may be any standard or proprietary housing, and may provide, for example, electromagnetic shielding and environmental protection for the components of chip package 300. The one or more dies 302 may be conductively coupled to a package substrate 306 using connections 308, which may be implemented with any number of standard or proprietary connection mechanisms, such as solder bumps, ball grid array (BGA), pins, or wire bonds, to name a few examples. Package substrate 306 may be any standard or proprietary package substrate, but in some cases includes a dielectric material having conductive pathways (e.g., including conductive vias and lines) extending through the dielectric material between the faces of package substrate 306, or between different locations on each face. In some embodiments, package substrate 306 may have a thickness less than 1 millimeter (e.g., between 0.1 millimeters and 0.5 millimeters), although any number of package geometries can be used. Additional conductive contacts 312 may be disposed at an opposite face of package substrate 306 for conductively contacting, for instance, a printed circuit board (PCB). One or more vias 310 extend through a thickness of package substrate 306 to provide conductive pathways between one or more of connections 308 to one or more of contacts 312. Vias 310 are illustrated as single straight columns through package substrate 306 for ease of illustration, although other configurations can be used (e.g., damascene, dual damascene, through-semiconductor via, or an interconnect structure that meanders through the thickness of substrate 306 to contact one or more intermediate locations therein). In still other embodiments, vias 310 are fabricated by multiple smaller stacked vias, or are staggered at different locations across package substrate 306. In the illustrated embodiment, contacts 312 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 312, to inhibit shorting.

In some embodiments, a mold material 314 may be disposed around the one or more dies 302 included within housing 304 (e.g., between dies 302 and package substrate 306 as an underfill material, as well as between dies 302 and housing 304 as an overfill material). Although the dimensions and qualities of the mold material 314 can vary from one embodiment to the next, in some embodiments, a thickness of mold material 314 is less than 1 millimeter. Example materials that may be used for mold material 314 include epoxy mold materials, as suitable. In some cases, the mold material 314 is thermally conductive, in addition to being electrically insulating.

### Methodology

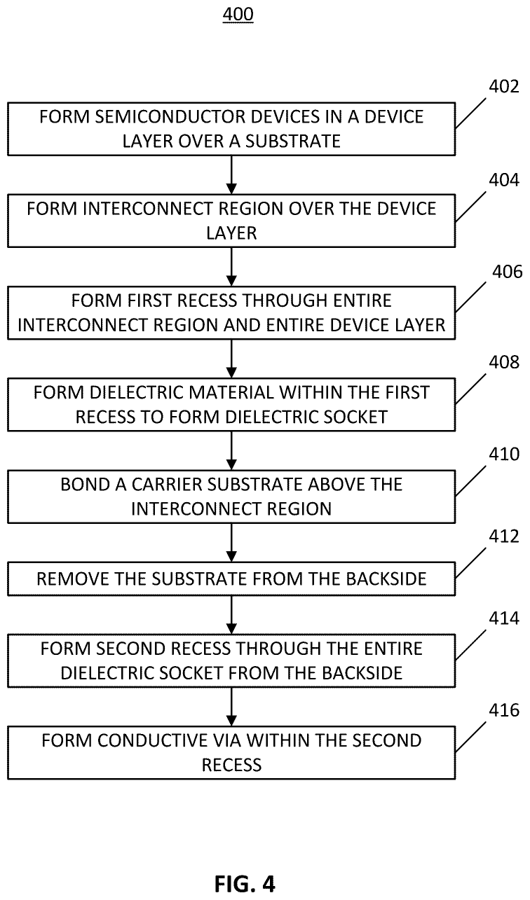

FIG. 4 is a flow chart of a method 400 for forming at least a portion of an integrated circuit, according to an embodiment. Various operations of method 400 may be illustrated in FIGS. 2A-2G. However, the correlation of the various operations of method 400 to the specific components illustrated in the aforementioned figures is not intended to imply any structural and/or use limitations. Rather, the aforementioned figures provide one example embodiment of method 400. Other operations may be performed before, during, or after any of the operations of method 400. Some of the operations of method 400 may be performed in a different order than the illustrated order.

Method 400 begins with operation 402 where any number of semiconductor devices are formed in a device layer over a substrate. The semiconductor devices may include trigate (e.g., finFET) devices, gate-all-around devices (e.g., employing nanowire or nanoribbon channels), forksheet devices, or planar devices. In some examples, the device layer includes more than one semiconductor layer to facilitate the formation of released nanoribbons, nanowires, or nanosheets in the semiconductor devices. Metal gate structures and metal contact structures may also be formed within or partially within the device layer.

Method 400 continues with operation 404 where an interconnect region is formed over the device layer. According to some embodiments, the interconnect region includes any number of stacked interconnect layers. Each interconnect layer includes a suitable dielectric material with any number of conductive interconnect structures patterned in the dielectric material. The conductive interconnect structures include conductive vias and conductive traces to route signals and power to or between any of the semiconductor devices.

Method 400 continues with operation 406 where a first recess is formed through an entire thickness of the interconnect region and the device layer. According to some embodiments, an anisotropic RIE process is used to form the first recess through the various materials of the interconnect region and the device layer. In some examples, the first recess extends into a portion of the substrate beneath the device layer. The first recess may have a greatest width along the mouth of the first recess between about 5 micrometers and about 10 micrometers. A natural taper may result from the etching process such that the bottom of the first recess has a width that is, for example, at least 50 nm, at least 100 nm, or at least 150 nm smaller than the width at the mouth of the first recess. Other examples may have different dimensions, or not be tapered.

Method 400 continues with operation 408 where a dielectric material is formed within the first recess to create a dielectric socket. Any number of dielectric materials may be deposited within the first recess to form the dielectric socket. In some examples, the dielectric socket includes silicon dioxide, silicon nitride, or silicon oxynitride. The entire volume of the first recess may be substantially filled with a single or multiple dielectric materials. Since the dielectric socket follows the profile of the first recess, the dielectric socket may also have a tapered profile with a top surface having a first width, for example, between about 5 micrometers and about 10 micrometers and a bottom surface having a second width that is at least 50 nm, at least 100 nm, or at least 150 nm smaller than the first width.

Method 400 continues with operation 410 where a carrier substrate is bonded above the interconnect region. In some examples, the carrier substrate is bonded to a topmost surface of the interconnect region (e.g., to a top surface of the topmost interconnect layer). The carrier substrate may include any suitable circuit substrate material, such as a semiconductor material or a glass substrate. The carrier substrate may be bonded to the interconnect region using any suitable bonding technique, such as direct wafer bonding, plasma bonding, eutectic bonding, or anodic bonding.

Method 400 continues with operation 412 where at least a portion of the substrate is removed from the backside of the integrated circuit. The substrate may be removed using any number of or combination of techniques such as dry etching, wet etching, polishing, or grinding. In some examples, the backside of the substrate is polished or grinded down until the lower surface of the dielectric socket is exposed. In some examples, the backside of the substrate is polished or grinded down until the lower surface of one or more materials within the device layer are exposed. In some embodiments, one or more dielectric layers may be formed beneath the device layer (e.g., directly on a bottom surface of the device layer) following the removal of the substrate.

Method 400 continues with operation 414 where a second recess is formed through the entire height of the dielectric socket from the backside of the integrated circuit. Another RIE process may be used to etch through the dielectric socket and any backside dielectric layers deposited below the device layer. According to some embodiments, the second recess further extends into at least a portion of the carrier substrate. The second recess may be aligned within the dielectric socket such that no portions of the device layer or any interconnect layers of the interconnect region are exposed within the second recess. According to some embodiments, the second recess tapers inwards such that the width of the recess decreases along its depth (measured from the backside adjacent to the device layer towards the frontside adjacent to the carrier substrate). In some examples, the first width at the mouth of the second recess is between about 2 micrometers and about 8 micrometers and the second width at the opposite end of the second recess is at least 50 nm, at least 100 nm, or at least 150 nm smaller than the first width at the mouth of the second recess.

Method 400 continues with operation 416 where a conductive via is formed within the second recess. According to some embodiments, one or more conductive materials are deposited within the second recess from the backside to form the conductive via. Any suitable conductive material can be used, such as any of copper, ruthenium, tungsten, cobalt, molybdenum, or alloys thereof, to name a few examples. In some examples, the via includes a conductive liner and a conductive fill on the conductive liner. The conductive liner may be a barrier layer material (such as tantalum nitride or titanium nitride), and the conductive fill includes any of copper, ruthenium, tungsten, cobalt, or molybdenum.

According to some embodiments, the conductive via follows the tapered profile of the second recess. Accordingly, the conductive via may have a first width at its bottom surface between, for example, about 2 micrometers and about 8 micrometers, such as between about 4 micrometers and about 5 micrometers, and a second width at its top surface that is at least 50 nm, at least 100 nm, or at least 150 nm less than its first width. Examples of such a dual reverse taper structure are shown in FIGS. 2G and 2G′, where the dielectric socket tapers inward from top to bottom, and the conductive via tapers inward from bottom to top. Such a configuration may be indicative that a first frontside pattern is used to provision the dielectric socket, and a second backside pattern is used to provision the conductive via.

### Example System

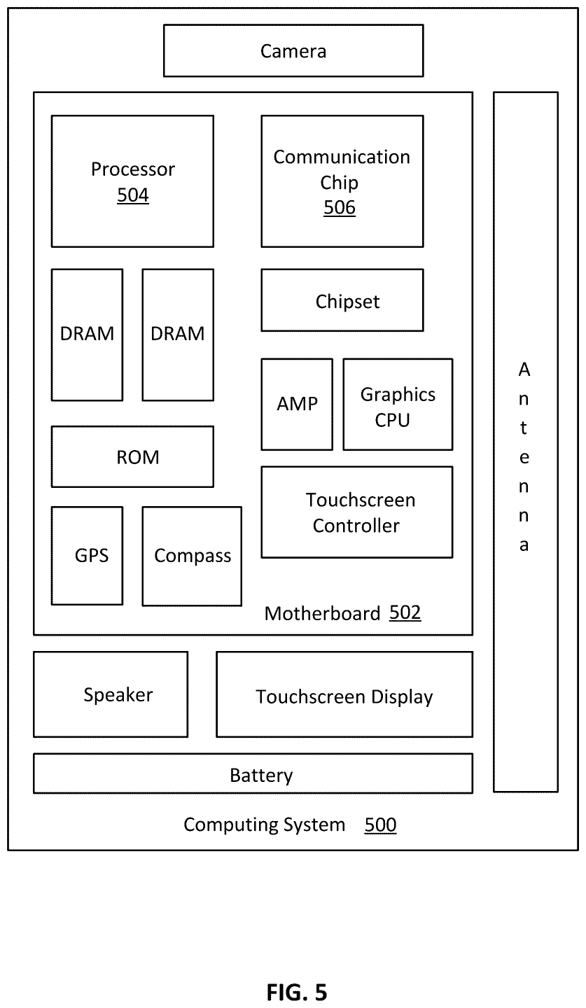

FIG. 5 is an example computing system implemented with one or more of the integrated circuit structures as disclosed herein, in accordance with some embodiments of the present disclosure. As can be seen, the computing system 500 houses a motherboard 502. The motherboard 502 may include a number of components, including, but not limited to, a processor 504 and at least one communication chip 506, each of which can be physically and electrically coupled to the motherboard 502, or otherwise integrated therein. As will be appreciated, the motherboard 502 may be, for example, any printed circuit board (PCB), whether a main board, a daughterboard mounted on a main board, or the only board of system 500, etc.

Depending on its applications, computing system 500 may include one or more other components that may or may not be physically and electrically coupled to the motherboard 502. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 500 may include one or more integrated circuit structures or devices configured in accordance with any of the embodiments disclosed herein (e.g., a module including an integrated circuit having a via connected to a backside conductive layer and extending through an entire thickness of a frontside interconnect region within a dielectric socket). In some embodiments, multiple functions can be integrated into one or more chips (e.g., for instance, note that the communication chip 506 can be part of or otherwise integrated into the processor 504).

The communication chip 506 enables wireless communications for the transfer of data to and from the computing system 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing system 500 includes an integrated circuit die packaged within the processor 504. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 506 also may include an integrated circuit die packaged within the communication chip 506. In accordance with some such example embodiments, the integrated circuit die of the communication chip includes one or more semiconductor devices as variously described herein. As will be appreciated in light of this disclosure, note that multi-standard wireless capability may be integrated directly into the processor 504 (e.g., where functionality of any chips 506 is integrated into processor 504, rather than having separate communication chips). Further note that processor 504 may be a chip set having such wireless capability. In short, any number of processor 504 and/or communication chips 506 can be used. Likewise, any one chip or chip set can have multiple functions integrated therein.

In various implementations, the computing system 500 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 500 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit that includes a plurality of semiconductor devices within a device layer, a first interconnect region above the device layer and having a plurality of first interconnect layers, a second interconnect region below the device layer and having one or more second interconnect layers, a dielectric structure extending through an entire thickness of the first interconnect region and an entire thickness of the device layer, and a conductive via extending through an entire thickness of the dielectric structure and contacting at least one conductive layer within any of the one or more second interconnect layers.

Example 2 includes the integrated circuit of Example 1, wherein the dielectric structure includes a top surface having a first width along a first direction and a bottom surface having a second width along the first direction, the top surface being adjacent to a top surface of the first interconnect region and the bottom surface being adjacent to a top surface of the second interconnect region, the first width being at least 50 nm greater than the second width.

Example 3 includes the integrated circuit of Example 2, wherein the first width is between about 5 and 10 micrometers.

Example 4 includes the integrated circuit of Example 2 or 3, wherein the conductive via includes a top surface having a third width along the first direction and a bottom surface having a fourth width along the first direction, wherein the fourth width is at least 50 nm greater than the third width.

Example 5 includes the integrated circuit of any one of Examples 1-4, wherein the conductive via has a width between about 2 and 8 micrometers.

Example 6 includes the integrated circuit of any one of Examples 1-5, wherein the dielectric structure comprises silicon and nitrogen.

Example 7 includes the integrated circuit of any one of Examples 1-6, further comprising a substrate bonded to a top surface of the first interconnect region.

Example 8 includes the integrated circuit of Example 7, wherein the conductive via extends into the substrate.

Example 9 includes the integrated circuit of any one of Examples 1-8, wherein the conductive via comprises copper or tungsten.

Example 10 includes the integrated circuit of any one of Examples 1-9, wherein a top surface of the dielectric structure is substantially coplanar with a top surface of the first interconnect region.

Example 11 includes the integrated circuit of any one of Examples 1-10, wherein the at least one conductive layer comprises a power or ground rail.

Example 12 includes the integrated circuit of any one of Examples 1-11, further comprising a third interconnect region above a top surface of the first interconnect region.

Example 13 includes the integrated circuit of Example 12, wherein the third interconnect region includes one or more additional interconnect layers.

Example 14 includes the integrated circuit of any one of Examples 1-13, wherein the dielectric structure has an outermost width that tapers inward as the dielectric structure progresses downward from its topmost surface to its bottommost surface, and the conductive via has an outermost width that tapers inward as the conductive via progresses upward from its bottommost surface to its topmost surface.

Example 15 is a printed circuit board that includes the integrated circuit of any one of Examples 1-14.

Example 16 is an electronic device that includes a chip package having one or more dies. At least one of the one or more dies includes a device layer comprising one or more semiconductor devices, a first interconnect region above the device layer and having a plurality of first interconnect layers, a second interconnect region below the device layer and having one or more second interconnect layers, a dielectric structure extending through an entire thickness of the first interconnect region and an entire thickness of the device layer, and a conductive via extending through an entire thickness of the dielectric structure and contacting at least one conductive layer within any of the one or more second interconnect layers.

Example 17 includes the electronic device of Example 16, wherein the dielectric structure includes a top surface having a first width along a first direction and a bottom surface having a second width along the first direction, the top surface being adjacent to a top surface of the first interconnect region and the bottom surface being adjacent to a top surface of the second interconnect region, the first width being at least 50 nm greater than the second width.

Example 18 includes the electronic device of Example 17, wherein the first width is between about 5 and 10 micrometers.

Example 19 includes the electronic device of Example 17 or 18, wherein the conductive via includes a top surface having a third width along the first direction and a bottom surface having a fourth width along the first direction, wherein the fourth width is at least 50 nm greater than the third width.

Example 20 includes the electronic device of any one of Examples 16-19, wherein the conductive via has a width between about 2 and 8 micrometers.

Example 21 includes the electronic device of any one of Examples 16-20, wherein the dielectric structure comprises silicon and nitrogen.

Example 22 includes the electronic device of any one of Examples 16-21, wherein the at least one of the one or more dies further comprises a substrate bonded to a top surface of the first interconnect region.

Example 23 includes the electronic device of Example 22, wherein the conductive via extends into the substrate.

Example 24 includes the electronic device of any one of Examples 16-23, wherein the conductive via comprises copper or tungsten.

Example 25 includes the electronic device of any one of Examples 16-24, wherein a top surface of the dielectric structure is substantially coplanar with a top surface of the first interconnect region.

Example 26 includes the electronic device of any one of Examples 16-25, wherein the at least one conductive layer comprises a power or ground rail.

Example 27 includes the electronic device of any one of Examples 16-26, further comprising a printed circuit board, wherein the chip package is attached to the printed circuit board.

Example 28 is a method of forming an integrated circuit. The method includes: forming any number of semiconductor devices in a device layer over a first substrate; forming an interconnect region over the device layer; forming a first recess through an entire thickness of the interconnect region and through an entire thickness of the device layer; forming one or more dielectric materials within the first recess to create a dielectric structure; bonding a second substrate to a top surface of the interconnect region; removing at least a portion of the first substrate; forming a second recess through an entire thickness of the dielectric structure from beneath the device layer; and forming one or more conductive materials within the second recess to create a conductive via.

Example 29 includes the method of Example 28, wherein forming the second recess comprises forming the second recess through at least a portion of an entire thickness of the second substrate.

Example 30 includes the method of Example 29, further comprising recessing a top surface of the second substrate to expose a top surface of the conductive via within the second substrate.

Example 31 includes the method of any one of Examples 28-30, wherein the interconnect region is a first interconnect region, the method further comprising forming a second interconnect region beneath the device layer, wherein at least one conductive layer of the second interconnect region contacts the conductive via.

Example 32 is an integrated circuit that includes a device layer comprising any number of semiconductor devices, a first interconnect region above the device layer and having a plurality of first interconnect layers, a second interconnect region below the device layer and having one or more second interconnect layers, a dielectric structure extending through an entire thickness of the first interconnect region and an entire thickness of the device layer, and a conductive via extending through an entire thickness of the dielectric structure and contacting at least one conductive layer within any of the one or more second interconnect layers. The dielectric structure has a tapered profile such that a top surface of the dielectric structure adjacent to a top surface of the first interconnect region is wider than a bottom surface of the dielectric structure adjacent to a top surface of the second interconnect region. The conductive via has a tapered profile such that a bottom surface of the conductive via is wider than a top surface of the conductive via.

Example 33 includes the integrated circuit of Example 32, wherein the top surface of the dielectric structure is at least 50 nm wider than the bottom surface of the dielectric structure.

Example 34 includes the integrated circuit of Example 32 or 33, wherein the bottom surface of the conductive via is at least 50 nm wider than the top surface of the conductive via.

Example 35 includes the integrated circuit of any one of Examples 32-34, wherein the top surface of the dielectric structure has a width between about 5 and 10 micrometers.

Example 36 includes the integrated circuit of any one of Examples 32-35, wherein the bottom surface of the conductive via has a width between about 2 and 8 micrometers.

Example 37 includes the integrated circuit of any one of Examples 32-36, wherein the dielectric structure comprises silicon and nitrogen.

Example 38 includes the integrated circuit of any one of Examples 32-37, further comprising a substrate bonded to a top surface of the first interconnect region.

Example 39 includes the integrated circuit of Example 38, wherein the conductive via extends into the substrate.

Example 40 includes the integrated circuit of any one of Examples 32-39, wherein the conductive via comprises copper or tungsten.

Example 41 includes the integrated circuit of any one of Examples 32-40, wherein the top surface of the dielectric structure is substantially coplanar with the top surface of the first interconnect region.

Example 42 includes the integrated circuit of any one of Examples 32-41, wherein the at least one conductive layer comprises a power or ground rail.

Example 43 includes the integrated circuit of any one of Examples 32-42, wherein the first interconnect region comprises one or more third layers above the plurality of first interconnect layers.

Example 44 includes the integrated circuit of Example 43, wherein the one or more third layers includes one or more additional interconnect layers and/or an additional device layer.

Example 45 is a printed circuit board that includes the integrated circuit of any one of Examples 32-44.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit, comprising:
a plurality of semiconductor devices within a device layer;
a first interconnect region above the device layer, the first interconnect region comprising a plurality of first interconnect layers;
a second interconnect region below the device layer, the second interconnect region comprising one or more second interconnect layers;
a dielectric structure extending through an entire thickness of the first interconnect region and an entire thickness of the device layer; and
a conductive via extending through an entire thickness of the dielectric structure and contacting at least one conductive layer within any of the one or more second interconnect layers.

2. The integrated circuit of claim 1, wherein the dielectric structure includes a top surface having a first width along a first direction and a bottom surface having a second width along the first direction, the top surface being adjacent to a top surface of the first interconnect region and the bottom surface being adjacent to a top surface of the second interconnect region, the first width being at least 50 nm greater than the second width.

3. The integrated circuit of claim 2, wherein the conductive via includes a top surface having a third width along the first direction and a bottom surface having a fourth width along the first direction, wherein the fourth width is at least 50 nm greater than the third width.

4. The integrated circuit of claim 1, further comprising a substrate bonded to a top surface of the first interconnect region.

5. The integrated circuit of claim 4, wherein the conductive via extends into the substrate.

6. The integrated circuit of claim 1, wherein a top surface of the dielectric structure is substantially coplanar with a top surface of the first interconnect region.

7. The integrated circuit of claim 1, wherein the dielectric structure has an outermost width that tapers inward as the dielectric structure progresses downward from its topmost surface to its bottommost surface, and the conductive via has an outermost width that tapers inward as the conductive via progresses upward from its bottommost surface to its topmost surface.

8. A printed circuit board comprising the integrated circuit of claim 1.

9. An electronic device, comprising:
a chip package comprising one or more dies, at least one of the one or more dies comprising
a device layer comprising one or more semiconductor devices;
a first interconnect region above the device layer, the first interconnect region comprising a plurality of first interconnect layers;
a second interconnect region below the device layer, the second interconnect region comprising one or more second interconnect layers;
a dielectric structure extending through an entire thickness of the first interconnect region and an entire thickness of the device layer; and
a conductive via extending through an entire thickness of the dielectric structure and contacting at least one conductive layer within any of the one or more second interconnect layers.

10. The electronic device of claim 9, wherein the dielectric structure includes a top surface having a first width along a first direction and a bottom surface having a second width along the first direction, the top surface being adjacent to a top surface of the first interconnect region and the bottom surface being adjacent to a top surface of the second interconnect region, the first width being at least 50 nm greater than the second width.

11. The electronic device of claim 10, wherein the conductive via includes a top surface having a third width along the first direction and a bottom surface having a fourth width along the first direction, wherein the fourth width is at least 50 nm greater than the third width.

12. The electronic device of claim 9, wherein the at least one of the one or more dies further comprises a substrate bonded to a top surface of the first interconnect region.

13. The electronic device of claim 9, wherein a top surface of the dielectric structure is substantially coplanar with a top surface of the first interconnect region.

14. The electronic device of claim 9, further comprising a printed circuit board, wherein the chip package is attached to the printed circuit board.

15. An integrated circuit, comprising:
a device layer comprising one or more semiconductor devices;
a first interconnect region above the device layer, the first interconnect region comprising a plurality of first interconnect layers;
a second interconnect region below the device layer, the second interconnect region comprising one or more second interconnect layers;
a dielectric structure extending through all of the first interconnect layers and an entire thickness of the device layer, the dielectric structure having a tapered profile such that a top surface of the dielectric structure adjacent to an uppermost surface of the first interconnect layers is wider than a bottom surface of the dielectric structure adjacent to a top surface of the second interconnect region; and
a conductive via extending through an entire thickness of the dielectric structure and contacting at least one conductive layer within any of the one or more second interconnect layers, the conductive via having a tapered profile such that a bottom surface of the conductive via is wider than a top surface of the conductive via.

16. The integrated circuit of claim 15, wherein the top surface of the dielectric structure is at least 50 nm wider than the bottom surface of the dielectric structure.

17. The integrated circuit of claim 15, wherein the bottom surface of the conductive via is at least 50 nm wider than the top surface of the conductive via.

18. The integrated circuit of claim 15, further comprising a substrate bonded to a top surface of the first interconnect region.

19. The integrated circuit of claim 18, wherein the conductive via extends into the substrate.

20. The integrated circuit of claim 15, wherein the top surface of the dielectric structure is substantially coplanar with the top surface of the first interconnect region.
